(19) United States
(12) Patent Application Publication
(10) Pub. No.: US 2010/0207257 A1
(43) Pub. Date: Aug. 19, 2010

(54) SEMICONDUCTOR PACKAGE AND MANUFACTURING METHOD THEREOF

(75) Inventor: Seokwon Lee, Kyunggi-Do (KR)

Correspondence Address: COOLEY LLP;ATTN: Patent Group, Suite 1100, 777 - 6th Street, NW, WASHINGTON, DC, 20001, US

(73) Assignee: Advanced Semiconductor Engineering, Inc., Kaohsiung (TW)

(21) Appl. No.: 12/372,133

(22) Filed: Feb. 17, 2009

(51) Int. Cl. H01L 23/552; H01L 21/56

(52) U.S. Cl. 257/660; 438/108; 257/E23.114; 257/E21.502

(57) ABSTRACT

A semiconductor package including at least a sensing component and a shielding layer is provided. While the shielding layer disposed over the molding compound can protect the semiconductor package from EMI radiations, the sensing component of the package is not blocked by the shielding layer for the feasibility of receiving the sensing signal.

### BACKGROUND OF THE INVENTION

1. Field of the Invention

The present invention relates to a semiconductor package, and more particularly to a semiconductor package having a sensing component.

2. Description of Related Art

For most electronic devices or packages, electromagnetic interference (EMI) is a common but undesirable disturbance that may interrupt, obstruct, degrade or limit the effective performance of the devices or the whole circuit. Especially, for micro-electro-mechanical system (MEMS) packages, different mechanical elements or components are integrated with various electronic devices, EMI disturbances may even aggravate.

Furthermore, due to the sophistication of MEMS packages, the need for better EMI shielding must be balanced with the packaging requirements of other mechanical components or devices. Conventionally, extra shielding plate or extra metal layer may be utilized according to the related art, which may be incompatible with the complicated packaging process or results in excessive design efforts.

### SUMMARY OF THE INVENTION

In view of the foregoing, the present invention is directed to a manufacturing method of a semiconductor package, which can simplify the manufacturing process without sacrificing effectiveness of EMI shielding.

The present invention is further directed to a MEMS package having at least a sensing component, which affords effective sensing capability and efficient EMI shielding.

The present invention provides a semiconductor package including a carrier, at least a chip and at least a sensing component disposed on the carrier, a molding compound and a shielding layer. The molding compound encapsulates the chip, a portion of the sensing component and a portion of the carrier. The sensing surface of the sensing component is partially exposed by an opening of the molding compound. The shielding layer is disposed over the molding compound without covering the opening of the molding compound.

The present invention also provides a semiconductor package including a carrier having a through-hole, at least a chip disposed on the carrier, at least a sensing component disposed on the carrier, a molding compound and a shielding layer. The sensing component is partially exposed by the through-hole of the carrier. The molding compound encapsulates the chip, a portion of the sensing component and a portion of the carrier. The shielding layer is disposed over the molding compound without covering the opening of the molding compound.

According to embodiments of the present invention, the shielding layer can be made of solder materials or metal materials.

According to embodiments of the present invention, the sensing component is electrically connected to the carrier through a plurality of wires or bumps. The chip is electrically connected to the carrier of the semiconductor package though a plurality of wires or bumps.

The invention further provides a manufacturing method of a semiconductor package. After providing a carrier, at least a chip and at least a sensing component are fixed on the carrier. Later, a partial molding process is performed to form a molding compound over the carrier to encapsulate the chip, at least a portion of the sensing component and a portion of the carrier. During the partial molding process, an opening is formed in the molding compound to partially expose the sensing component. The shielding layer is then formed over the molding compound without covering the opening.

According to one embodiment of the present invention, the shielding layer is formed by a printing process or a plating process.

Based on the above, the shielding layer disposed over the molding compound functions as an EMI shield of the semiconductor package, while the sensing component is not blocked by the shielding layer. According to the present invention, by taking advantage of the through hole of the carrier, no extra molding effort is required and the sensing component can be exposed through the through hole. Therefore, the semiconductor package of the present invention offers EMI shielding effectiveness and efficient sensing performances.

In order to the make the aforementioned and other objects, features and advantages of the present invention comprehensible, several embodiments accompanied with figures are described in detail below.

### BRIEF DESCRIPTION OF THE DRAWINGS

FIG. 1 is a cross-sectional view of a semiconductor package according to an embodiment of the present invention.

FIGS. 2A through 2F are schematic views showing a manufacturing method of the semiconductor package according to a preferred embodiment of the present invention.

FIGS. 3A through 3E are schematic views showing a manufacturing method of the semiconductor package according to another preferred embodiment of the present invention.

FIG. 4 is a cross-sectional view of a semiconductor package according to another embodiment of the present invention.

### DESCRIPTION OF EMBODIMENTS

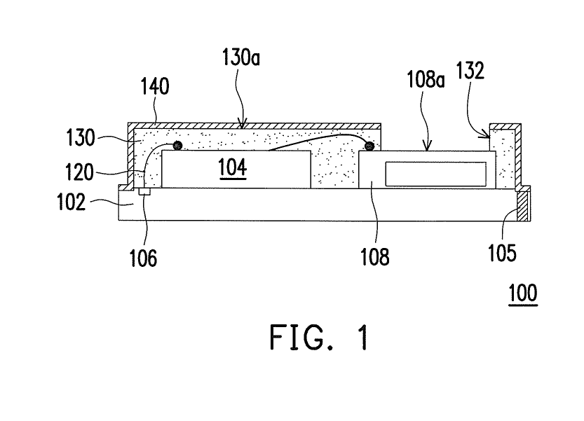

FIG. 1 is a cross-sectional view of a semiconductor package according to a preferred embodiment of the present invention. Referring to FIG. 1, the semiconductor package 100 of the present embodiment includes a carrier 102, at least a chip 104, at least a contact 106, at least a sensing component 108, a plurality of wires 120, a molding compound 130 and a shielding layer 140. The carrier 102 can be a laminated semiconductor substrate (for example, a laminated PCB board) or a leadframe. The sensing component 108 may include, for example, a sonic sensing element that is able to detect or sense sound waves. Preferably, the sonic sensing element can be a MEMS microphone. The sensing element 108 may be electrically connected to the chip 104 through wire 120, while the chip 104 is electrically connected to the contact 106 of the carrier 102 through wires 120. For example, the material of the shielding layer 140 may be a solder material or a metal material. The molding compound 130 encapsulates the chip 104, the contact 106, the wires 120, and a portion of the carrier 102. Besides, the molding compound 130 has an opening 132, and at least a portion of the top surface 108a of the sensing component 108 is exposed by the opening 132. The exposed top surface (the sensing surface) 108a of the sensing component 108 is responsible for detecting or sensing the target element (i.e. the sound wave or the acoustic wave). The shielding layer 140 is disposed over the molding compound 130, covering the exposed surface 130a (i.e. the top surface around the opening 132 and the four sidewalls) of the molding compound 130 but apart from covering the opening 132. In addition, the shielding layer 140 covers the ground vias 105 of the carrier 102, and the shielding layer 140 is electrically connected to the ground via 105 and grounded.

In the semiconductor package 100 of the present embodiment, the shielding layer disposed over the molding compound functions as an EMI shield, particularly protecting the package from the EMI radiation from the surrounding radiation sources.

In the present embodiment, the edge of the shielding layer may be aligned with the edges of the carrier. Besides, the semiconductor package of the present embodiment may further include passive components on the carrier for different functionality. In principle, the semiconductor package may be a MEMS package, especially a MEMS package having a sensing component therein.

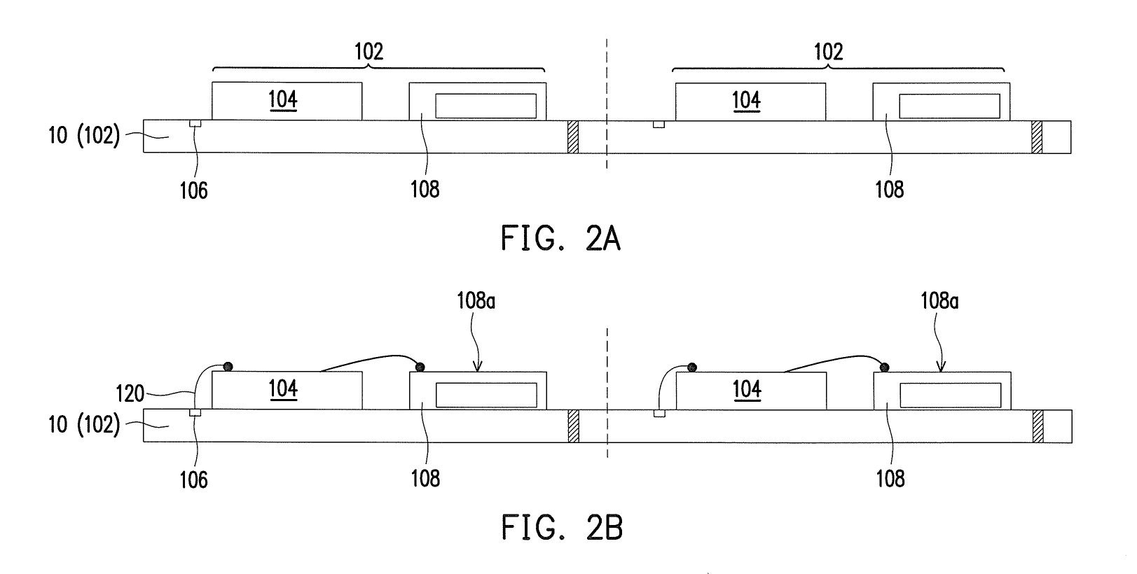

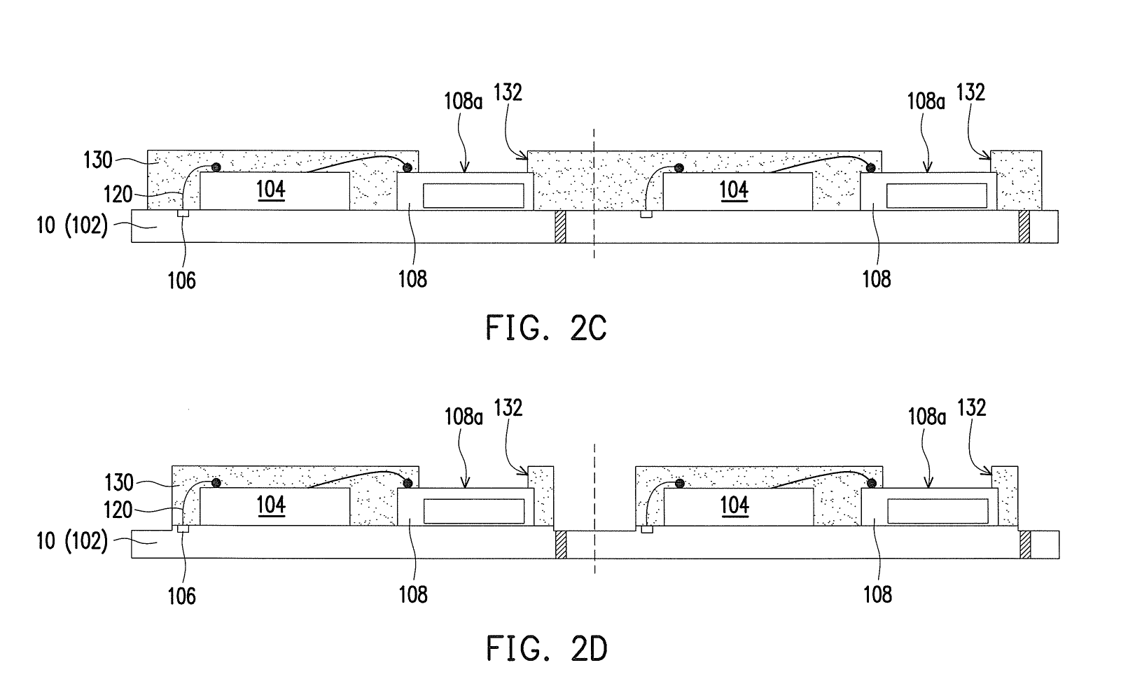

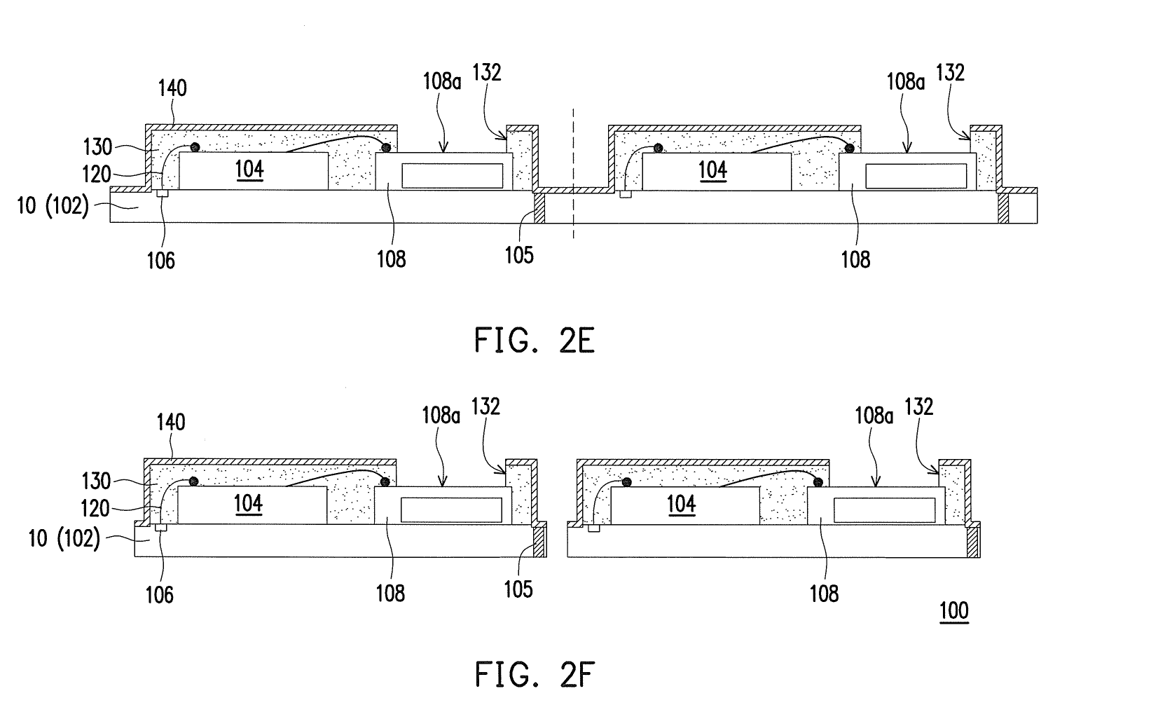

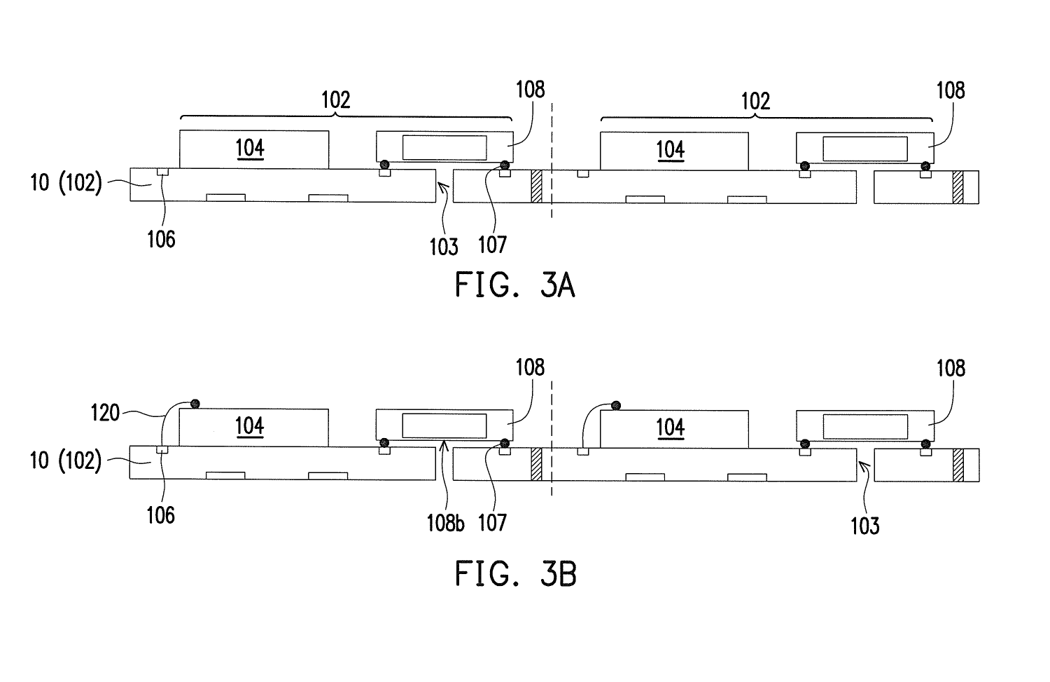

FIGS. 2A through 2F are schematic cross-sectional views showing a manufacturing method of the semiconductor package according to the preferred embodiment of the present invention.

Referring to FIG. 2A, an array carrier 10 having a plurality of carrier unit 102 and a plurality of contacts 106 is provided. The carrier unit 102 described hereafter can be considered as the carrier 102 in FIG. 1. At least one chip 104 and at least one sensing component 108 are disposed on the carrier unit 102. The chip 104 and the sensing component 108 can be attached to the carrier unit 102 through an adhesive material. The adhesive material can be epoxy glue or silicone glue, for example.

Referring to FIG. 2B, a plurality of wires 120 are formed for electrically connecting the chips 104 and the contacts 106 of the carrier units 102, and electrically connecting the chip 104 and the sensing component 108 within the same carrier unit 102. Alternatively, the chip 104 can be electrically connected to the carrier unit 102 via flip chip bonding technology, rather than wire bonding technology.

Referring to FIG. 2C, a partial molding process using, for example, rubber core pin technology or film mold technology, is carried out to form a molding compound 130 on the carrier unit 102 to encapsulate the chip 104, the contacts 106, the sensing component 108 and at least a portion of the carrier unit 102. During the molding process, certain protrusion parts of the mold correspondingly align with and touch the sensing component 108, so that the formed molding compound 130 has an opening 132 that exposes the top surface 108a of the sensing component 108. In general, the size of the opening 132 is smaller than or at most equal to that of the correspondingly exposed sensing component. Preferably, the opening is smaller in size, so that the sensing component is partially protected by the molding compound.

Referring to FIG. 2D, a half cutting process is performed to remove a portion of the molding compound 130 within the open area of the array carrier 10.

Referring to FIG. 2E, a shielding layer 140 is formed over the carrier 10 and over the exposed surface of the molding compound 130, but not covering the opening 132 or the underlying top surface 108a of the sensing component 108. The shielding layer 140 may be electrically connected with a ground via 105 of the carrier 10. The material of the shielding layer 140 can be a solder material formed by screen printing method or a metal material formed by a plating method, for example. As the shielding layer 140 is formed by printing or plating, the shielding layer 140 can be selectively formed to cover the molding compound and the carrier without blocking the perception of the sensing component 108.

Finally, as shown in FIG. 2F, a singulation process is performed to obtain the semiconductor package 100. It should be noted that the edge of the shielding layer 140 is aligned with the edge of the carrier unit 102 after singulation.

As the shielding layer formed over the molding compound can help the EMI shielding of the semiconductor package, the shielding layer does not hinder the sensing function of the sensing component by not covering the opening of the molding compound. The present invention provides a manufacturing method employing straightforward methods to selectively form the shielding layer over the molding compound. Moreover, the semiconductor package affords effective EMI shielding without compromising the sensing function of the sensing component for the semiconductor package.

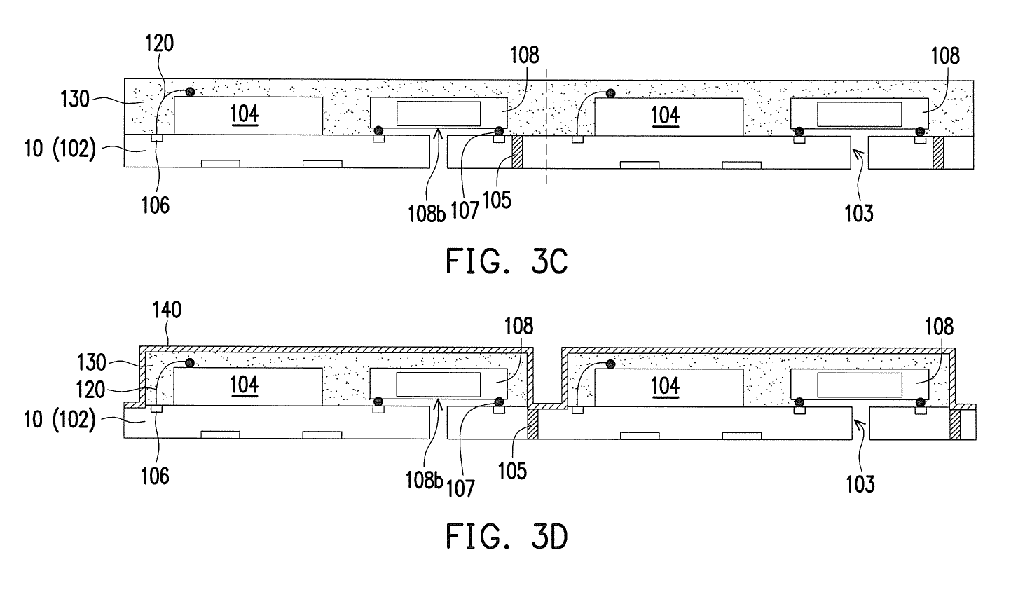

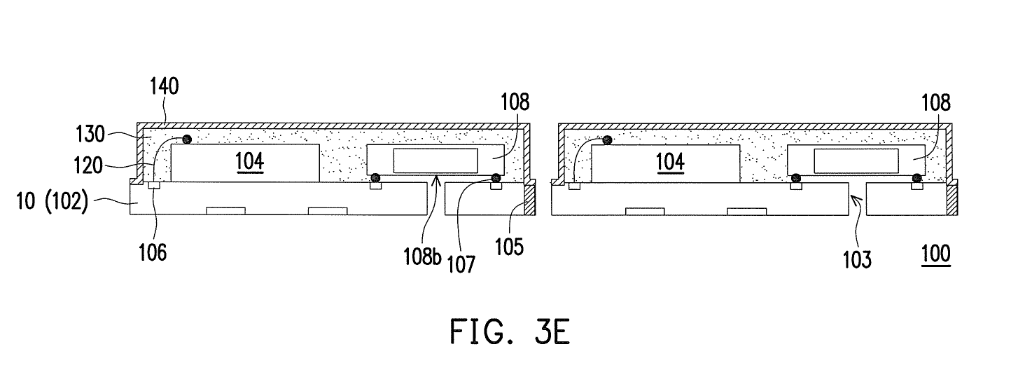

FIGS. 3A through 3E are schematic cross-sectional views showing a manufacturing method of the semiconductor package according to another preferred embodiment of the present invention.

Referring to FIG. 3A, an array carrier 10 having a plurality of carrier unit 102 and a plurality of contacts 106 is provided. The carrier unit 102 includes at least a through hole 103. At least one chip 104 and at least one sensing component 108 are disposed on the carrier unit 102. The sensing component 108 is electrically connected to the carrier unit 102 through a plurality of bumps 107. The chip 104 can be attached to the carrier unit 102 through an adhesive material. As the sensing component 108 is bonded to the carrier unit 102 in a flip-chip way, the sensing surface 108b (herein the bottom surface) faces downward and is exposed by the through hole 103. In general, the size of the through hole 103 is smaller than or at most equal to that of the correspondingly exposed sensing component. Preferably, the through hole is smaller in size, so that the sensing component is partially exposed by the through hole. However, the size of the through hole 103 is smaller than that of the distributed area of the bumps 107. For example, the bumps 107 are arranged along the outer, peripheral portion of the sensing component 108, while the through hole 103 exposes the sensing surface 108b located in the central portion of the sensing component 108.

Referring to FIG. 3B, a plurality of wires 120 are formed for electrically connecting the chips 104 and the contacts 106 of the carrier units 102. Alternatively, the chip 104 can be electrically connected to the carrier unit 102 via flip chip bonding technology, rather than wire bonding technology.

Referring to FIG. 3C, a molding process is carried out to form a molding compound 130 over the carrier unit 102 to encapsulate the chip 104, the contacts 106, and the sensing component 108 on the carrier unit 102. However, the molding compound 130 does not encapsulate the entire sensing component 108. Due to the hindrance of the bumps 107 located between the sensing component 108 and the carrier unit 102, the molding compound 130 will not fill up the space between the sensing surface 108b, the bumps 107 and the underneath portion of the carrier unit surrounding the through hole 103. Consequently, the sensing surface of the sensing component 108 can be exposed for receiving the sound wave.

Referring to FIG. 3D, a half cutting process is performed to remove a portion of the molding compound 130. Later, a shielding layer 140 is formed over the carrier 10 and over the exposed surface of the molding compound 130. The shielding layer 140 may be electrically connected with a ground via 105 of the carrier 10. The material of the shielding layer 140 can be a solder material or a metal material, for example. The shielding layer 140 can be formed by screen printing method, a sputtering method or a plating method, for example.

Finally, as shown in FIG. 3E, a singulation process is performed to fully cut through the array carrier 10, so that individual semiconductor packages 100 are obtained. It should be noted that the edge of the shielding layer 140 is aligned with the edge of the carrier unit 102 after singulation.

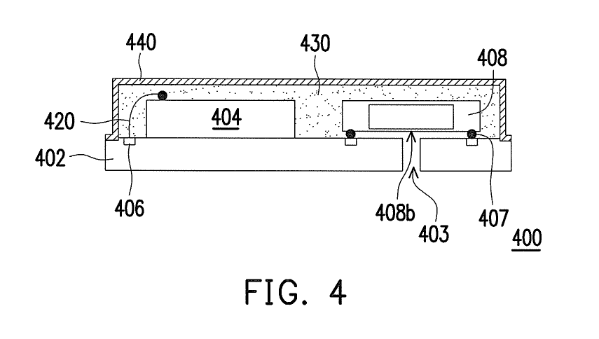

Accordingly, for the semiconductor package of the present invention, the sensing component may be electrically connected to the carrier through flip chip bonding technology, rather than wire bonding technology described in the previous embodiment. As shown in FIG. 4, the major differences lie in that the semiconductor package 400 includes the sensing component 408 electrically connected to the contacts 406 of the carrier 402 through bumps 407 sandwiched there-between. The sensing component 408 is partially exposed by the through hole 403 of the carrier 402. The shielding layer 440 disposed over the surface of the molding compound 430 functions as the EMI shield. Taking advantages of the bumps sandwiched between the sensing component and the carrier, there is a void space existing between the sensing surface 408b of the sensing component 408, the top surface of the carrier 402 and the through hole 403, so that the sensing surface of the sensing component is exposed for the feasibility of receiving sound wave. Preferably, the void space existing in the molding compound is bigger or equivalent in size, when compared with the sensing surface of the sensing component, so that the sensing surface 408b is completely exposed by the void.

In summary, the shielding layer over the molding compound can efficiently shelter the package of the present invention from the outside EMI radiation, thus enhancing the EMI shielding. According to the manufacturing processes disclosed in the present invention, it is possible to expose the sensing component by either partial molding process or take advantage of the pre-formed through hole of the carrier. Additionally, as the EMI shield can be selectively formed over the molding compound without blocking the sensing component, it is unnecessary to compromise the sensing capability of the sensing component for EMI shielding of the package. Accordingly, such design is compatible with the packaging of sensing components, particularly, MEMS packaging of sonic sensing components.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A semiconductor package, comprising:
a carrier;
at least a chip disposed on and electrically connected to the carrier;
at least a sensing component disposed on the carrier;
a molding compound, at least encapsulating the chip, a portion of the sensing component and a portion of the carrier, wherein the molding compound has an opening to expose at least a portion of a sensing surface of the sensing component; and
a shielding layer, disposed over and covering the molding compound except for covering the opening of the molding compound.

2. The semiconductor package as claimed in claim 1, wherein a size of the opening of the molding compound is smaller than or equivalent to that of the sensing surface of the sensing component.

3. The semiconductor package as claimed in claim 1, wherein the sensing component is electrically connected to the chip through at least a wire.

4. The semiconductor package as claimed in claim 1, wherein the sensing component is a sonic sensing component, and the carrier is a laminated substrate or a leadframe.

5. The semiconductor package as claimed in claim 1, wherein the shielding layer is electrically connected to at least a ground via of the carrier.

6. The semiconductor package as claimed in claim 1, a material of the shielding layer is a metal material.

7. A manufacturing method of a semiconductor package, comprising:
providing a carrier having a plurality of carrier units;
disposing at least a chip and at least a sensing component on the carrier unit, wherein the chip is electrically connected to the carrier unit and the sensing component is electrically connected to the carrier unit;
forming a molding compound on the carrier to encapsulate the chip and at least a portion of the sensing component in each carrier unit, but to expose at least a portion of a sensing surface of the sensing component in each carrier unit; and
forming a shielding layer over the molding compound without covering the exposed sensing surface of the sensing component in each carrier unit.

8. The method as claimed in claim 7, wherein the sensing component is electrically connected to the carrier through wire-bonding.

9. The method as claimed in claim 8, wherein forming the molding compound on the carrier includes forming the molding compound with an opening to expose at least a portion of the sensing surface of the sensing component by using a partial molding process.

10. The method as claimed in claim 7, wherein the sensing component is electrically connected to the carrier through flip-chip bonding.

11. The method as claimed in claim 10, wherein forming the molding compound on the carrier includes forming the molding compound with a void to expose the sensing surface of the sensing component.

12. The method as claimed in claim 7, further comprising performing a singulation process to cut through the carrier so as to obtain individual semiconductor packages after forming the shielding layer.

13. The method as claimed in claim 12, further comprising performing a half-cutting process to remove portions of the molding compound before forming the shielding layer.

14. The method as claimed in claim 7, wherein the shielding layer is formed by a screen printing process or a plating process.

15. The method as claimed in claim 7, wherein the shielding layer is formed to cover an exposed surface of the molding compound and at least a ground via of the carrier.

16. A semiconductor package, comprising:
a carrier having at least a through hole therein and a plurality of contacts thereon;
at least a chip disposed on and electrically connected to the contacts of the carrier;
at least a sensing component disposed on the carrier and electrically connected to the carrier though a plurality of bumps, wherein at least a portion of a sensing surface of the sensing component is exposed by the through hole of the carrier;
a molding compound, at least encapsulating the chip, the contacts, a portion of the sensing component and a portion of the carrier, wherein the sensing surface of the sensing component is exposed by a void existing in the molding compound; and
a shielding layer, disposed over and covering the molding compound.

17. The semiconductor package as claimed in claim 16, wherein a size of the void of the molding compound is bigger or equivalent to that of the sensing surface of the sensing component, and the sensing surface is completely exposed by the void.

18. The semiconductor package as claimed in claim 16, wherein the sensing component is a sonic sensing component, and the carrier is a laminated substrate or a leadframe.

19. The semiconductor package as claimed in claim 16, wherein the shielding layer is electrically connected to at least a ground via of the carrier.

20. The semiconductor package as claimed in claim 16, a material of the shielding layer is a metal material.
